(19) United States
(12) Patent Application Publication
(10) Pub. No.: US 2015/0364650 A1
(43) Pub. Date: Dec. 17, 2015

(54) LIGHT-EMITTING DEVICE AND METHOD OF MANUFACTURING THE SAME

(71) Applicant: Epistar Corporation, Hsinchu (TW)

(72) Inventors: Guan-Ru HE, Hsinchu (TW); Jui-Hung YEH, Hsinchu (TW)

(21) Appl. No.: 14/302,561

(22) Filed: Jun. 12, 2014

(51) Int. Cl. H01L 33/38; H01L 27/15; H01L 33/00

(52) U.S. Cl. CPC H01L 33/38; H01L 33/005; H01L 27/15; H01L 2933/0016

(57) ABSTRACT

The description discloses a lighting-emitting device and the method of manufacturing the same. A disclosed method of manufacturing a light-emitting device comprising providing a temporary substrate, forming a bonding pad on the temporary substrate, providing a first substrate, forming a light-emitting chip on the first substrate, connecting the light-emitting chip and the bonding pad layer.

### BACKGROUND

1. Technical Field

The present disclosure relates to a light-emitting device and the method of manufacturing the same, and in particular to a light-emitting device comprising a light-emitting chip, bonding pads and a eutectic interface between the light-emitting chip and the bonding pads.

2. Description of the Related Art

The light-emitting diodes (LEDs) of the solid-state lighting elements have the characteristics of low power consumption, low heat generation, long operational life, shockproof, small volume, quick response and good opto-electrical property like light emission with a stable wavelength so the LEDs have been widely used in household appliances, indicator light of instruments, and opto-electrical products, etc.

Though the LEDs have been widely used in light-emitting device in daily life, the method of manufacturing the LEDs has its drawbacks. Especially, when the LED is covered by a wavelength tuning material layer, such as layer comprising phosphor material, the wavelength tuning material layer might collapse during the process. The collapse of wavelength tuning material layer not only reduces the yield of mass production but also influences the COA (color over angle) of an LED.

### SUMMARY OF THE DISCLOSURE

A method of manufacturing a light-emitting device, comprising providing a temporary substrate; forming a bonding pad layer having a first width on the temporary substrate; providing a first substrate; forming a light-emitting chip having a second width on the first substrate; and connecting the light-emitting chip and the bonding pad. The first width is larger than the second width.

A light-emitting device, comprising a light-emitting chip comprising multiple electrodes; an optical layer on the light-emitting chip; multiple bonding pads connecting to the electrodes of the light-emitting chip; and a eutectic bonding interface between the electrodes and the bonding pads.

A light-emitting device, comprising a substrate; an array of light-emitting chips each comprising multiple electrodes on the substrate; an array of optical layers on the light-emitting chips respectively; and multiple bonding pads connecting to the multiple electrodes and the optical layers respectively, such that multiple eutectic bonding interfaces are formed between the multiple bonding pads and the multiple electrode correspondingly.

### BRIEF DESCRIPTION OF THE DRAWINGS

FIGS. 1a-1b show a top view and a cross-sectional view of a structure related to a light-emitting device in accordance with an embodiment of the present disclosure.

FIGS. 2a-2b show a top view and a cross-sectional view of a structure related to a light-emitting device in accordance with an embodiment of the present disclosure.

FIGS. 3a-3b show a top view and a cross-sectional view of a structure related to a light-emitting device in accordance with an embodiment of the present disclosure.

FIGS. 4-8 show a cross-sectional view of a structure related to a light-emitting device in accordance with an embodiment of the present disclosure.

FIG. 9 shows a cross-sectional view of a light-emitting device in accordance with an embodiment of the present disclosure.

FIG. 10 shows a cross-sectional view of a structure related to a light-emitting device in accordance with an embodiment of the present disclosure.

### DETAILED DESCRIPTION OF THE EMBODIMENTS

To better and concisely explain the disclosure, the same name or the same reference number given or appeared in different paragraphs or figures along the specification should has the same or equivalent meanings while it is once defined anywhere of the disclosure.

The following shows the description of the embodiments of the present disclosure in accordance with the drawings.

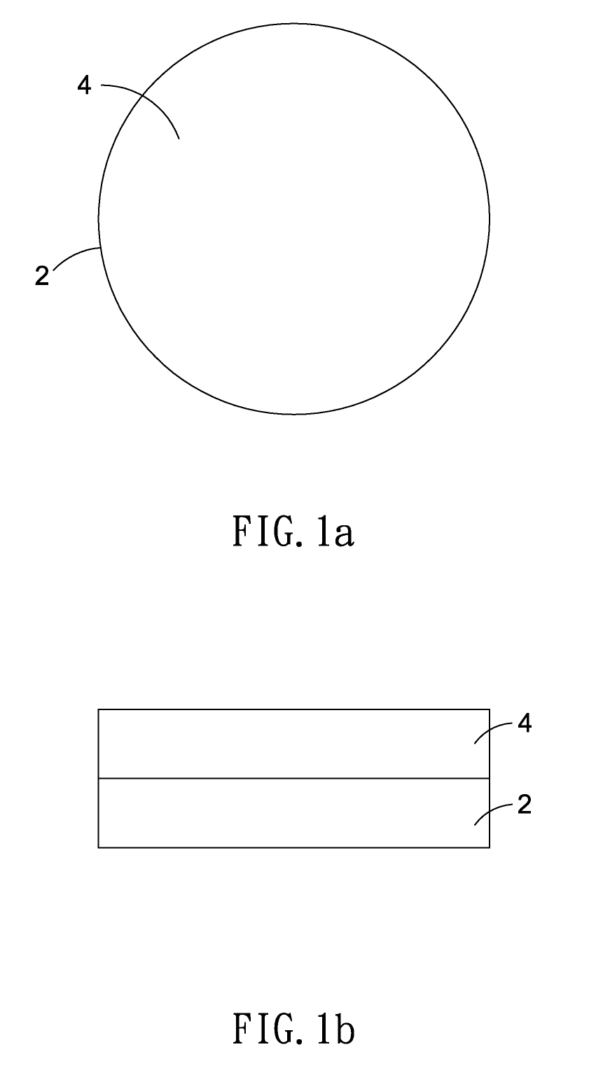

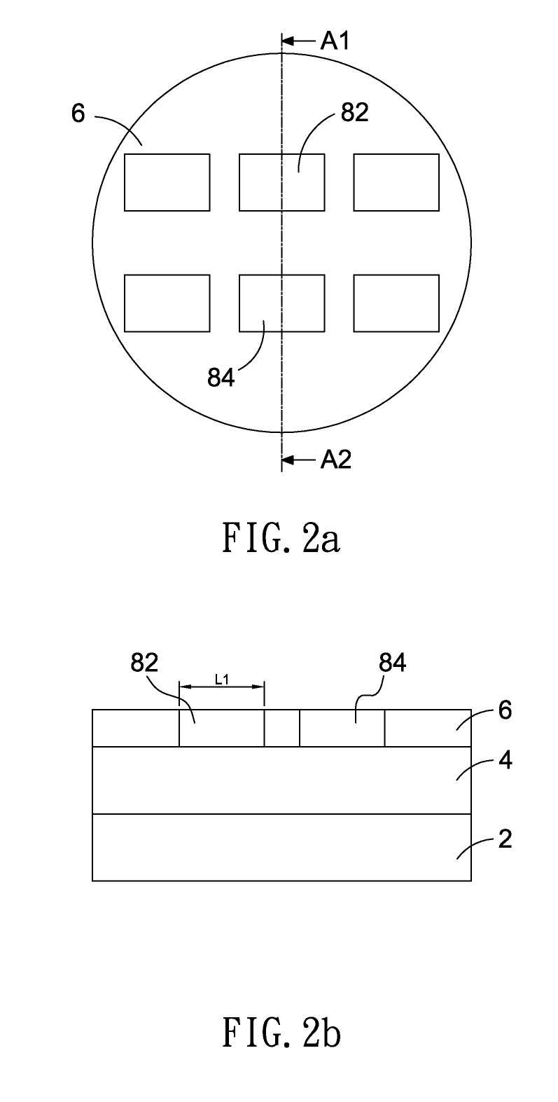

FIGS. 1a-1b show a top view and a cross-sectional view of a structure related to a light-emitting device 100 in accordance with an embodiment of the present disclosure. At the step of process depicted in FIGS. 1a-1b, a temporary substrate 2 is provided and a seed layer 4 is then formed on the temporary substrate 2. The seed layer 4 is for forming bonding pads later. As shown in FIGS. 2a-2b, a photoresist layer 6 and multiple bonding pads are formed on the seed layer 4. The FIG. 2b is a cross-sectional view of FIG. 2a along the line A₁-A₂. The photoresist layer 6 is formed on the seed layer 4 as a mask, and part of the photoresist layer 6 is etched to form an array of trenches to expose the seed layer 4. The etching process can be a lithography process or an etching process. Then, a metal material is formed in the trenches and contacted with the seed layer 4 to form the bonding pads which are surrounded by the photoresist layer 6 as shown in FIG. 2b.

The process of forming the bonding pads in the trenches can be deposition, and the material filled in the trenches comprises Cu, Ni, Au, W and Ti. The bonding pads comprise a first pad 82 and a second pad 84 arranged in a row to be connected to a same light-emitting chip, and the first pad 82 has a width L1. In this embodiment, the top surfaces of the bonding pads and the photoresist layer 6 opposing to the temporary substrate 2 are not flat. Since the flatness of the top surfaces affects the bonding strength between the chips and the bonding pads, a planarization process is needed to planarize the top surfaces so the height of the photoresist layer 6 can be about the same as that of the bonding pads, and the bonding strength between the chips and the bonding pads is therefore improved. Besides, the characteristics, such as the size and the shape, of the first pad 82 can be the same with or different from that of the second pad 84. Furthermore, the size can be the length, width, or the height.

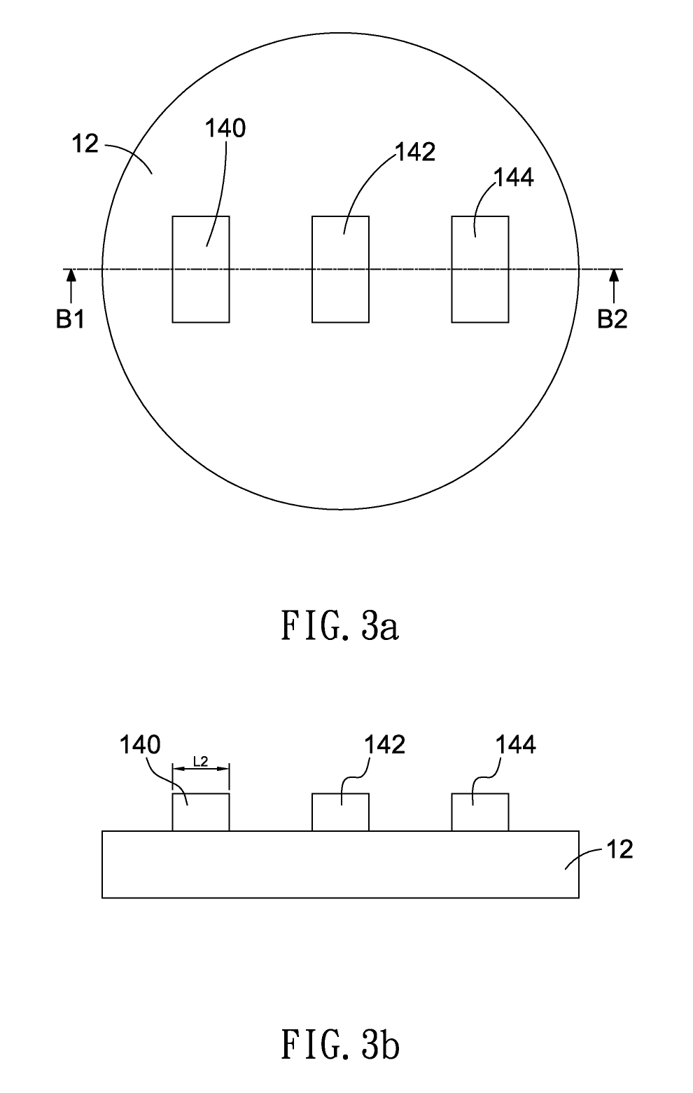

In the steps depicted in FIGS. 3a-3b, a first substrate 12 is provided and the light-emitting chips are placed on the first substrate 12. The FIG. 3b is a cross-sectional view of FIG. 3a along the line B₁-B₂. The light-emitting chips such as a first chip 140 with a width L2, a second chip 142, and a third chip 144 are placed with a space between each other, and each of the light-emitting chips comprises two electrodes (not shown). In another embodiment, the light-emitting chips are epitaxially grown on the first substrate 12 and the distances between any two light-emitting chips can be the same or be different from each other. The light-emitting chips are capable of emitting same or different incoherent visible or invisible lights. The visible lights can be same or different color; the invisible lights can be UV light or infrared light. In order to bond the light-emitting chips and the bonding pads, the light-emitting chips are arranged in an orientation corresponding to the positions of the bonding pads. For example, the second chip 142 is arranged to be connected to the first pad 82 and the second pad 84 in the following steps. Besides, in order to bond the bonding pads and the light-emitting chips, alignment marks (not shown in the figure) are optionally formed on the surface of the first substrate 12 and/or on the surface of the photoresist layer 6.

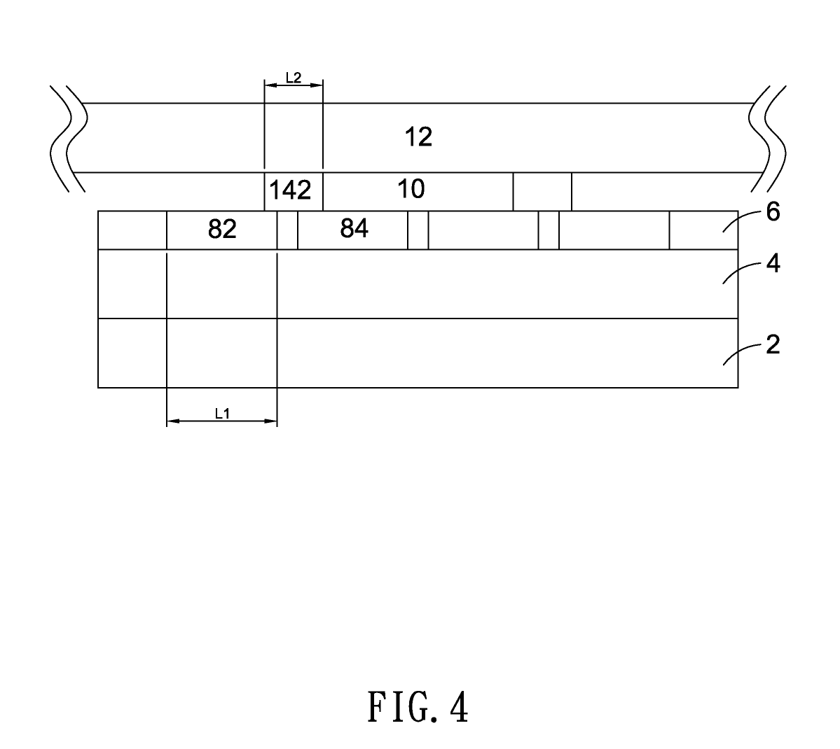

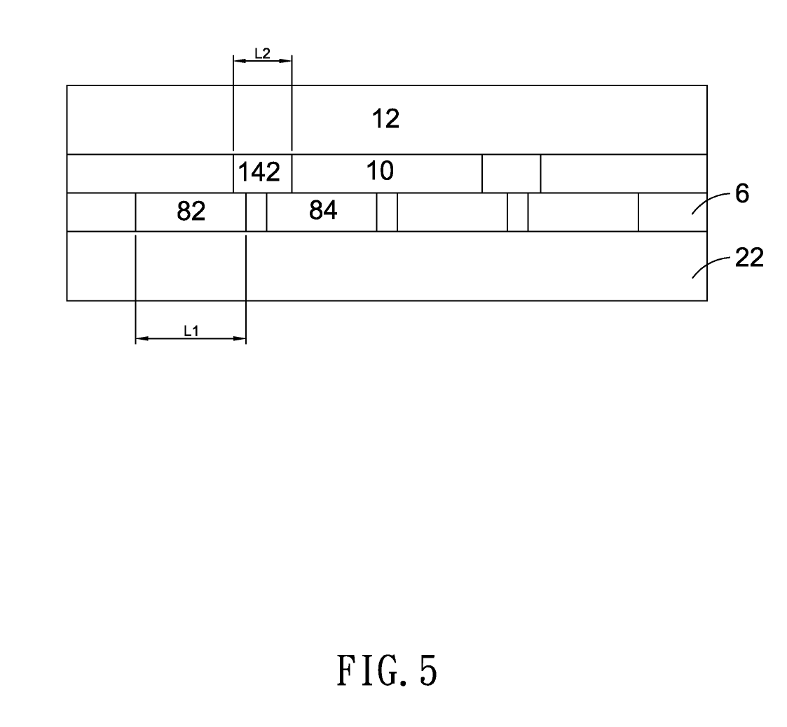

As shown in FIG. 4, the bonding pads in FIGS. 2a-2b and the light-emitting chips in FIGS. 3a-3b are bonded so gaps 10 are formed between the light-emitting chips, and a minimum distance between two adjacent bonding pads is different from that the gap 10. An alignment process is performed before bonding the bonding pads and the light-emitting chips, and the bonding process comprises increasing temperature and increasing pressure on the bonding pads and/or on the light-emitting chips. In this embodiment, the width L1 of the first pad 82 or the width of the second pad 84 is larger than the width L2 of the second chip 142 to facilitate the alignment of the connection. The alignment process can be performed by matching the positions of the flat sides on the circumferences of the carrier supporting the bonding pads and of the carrier supporting the light-emitting chips. Or, the alignment process can be performed by matching the positions of the alignment marks on the carriers. In this embodiment, the alignment process is performed by moving and rotating the carriers like the temporary substrate 2 and the first substrate 12 to match the flat side (not shown) of the temporary substrate 2 and flat side (not shown) of the first substrate 12. In another embodiment, the positions of the temporary substrate 2 and the first substrate 12 are adjusted to match the alignment marks on the first substrate 12 and on the temporary substrate 2. Then, the second chip 142 is bonded with the first pad 82 and the second pad 84 by eutectic bonding. After bonding, the temporary substrate 2 and the seed layer 4 are removed to expose a surface of the photoresist layer 6 opposing to the first substrate 12. A second substrate 22 is then connected to the surface as shown in FIG. 5. The minimum distance between adjacent two bonding pads is different from that between adjacent two light-emitting chips.

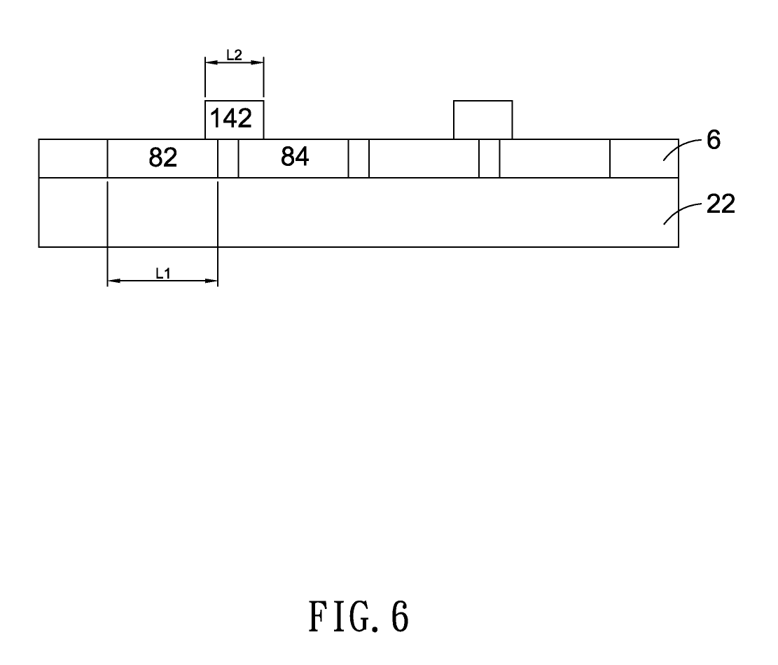

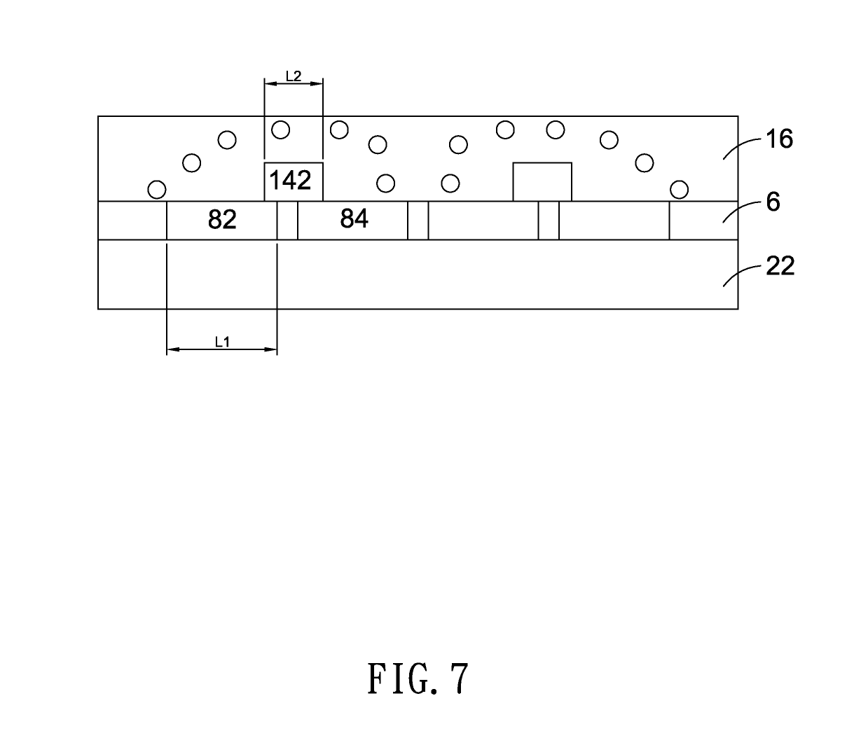

Referring to FIGS. 6˜7, the first substrate 12 is removed to expose a surface of the second chip 142 and a surface of the photoresist layer 6, and an optical layer 16 is formed on the light-emitting chips. The optical layer 16 covers the light-emitting chips, the bonding pads, and the photoresist layer 6. As shown in FIG. 7, the optical layer 16 is formed on top surfaces and sidewalls of the light-emitting chips. The optical layer 16 comprises a transparent material and a wavelength conversion material. The material of the transparent material can be silicone. In this embodiment, the optical layer 16 is formed by forming a first portion of the transparent material on the light-emitting chips, forming the wavelength conversion material on the first portion and forming a second portion of the optical layer 16 on the wavelength conversion material. The process of forming the wavelength conversion material can be deposition, coating, dispersing or spreading. Furthermore, the wavelength conversion material can be mixed with a transparent material which is a binder; also can be silicone. To be specific, the optical layer 16 forms a stack of “transparent material—wavelength conversion material—transparent material”. In this embodiment, the transparent material and the wavelength conversion material are formed on the second substrate 22. In another embodiment, the optical layer 16 is formed in advance by forming a mixture comprising a transparent material and a wavelength conversion material, curing the mixture to form a strip or a sheet, and attaching the strip or sheet on the light-emitting chips. The optical layer 16 can also be formed as an array of strips or sheets in advance and then attached to the light-emitting chips. The particles of the wavelength conversion material can be distributed in the optical layer 16 uniformly, randomly or close to the surfaces of light extraction of the light-emitting chips. In other words, the particles can be distant from or in contact with the second chip 142.

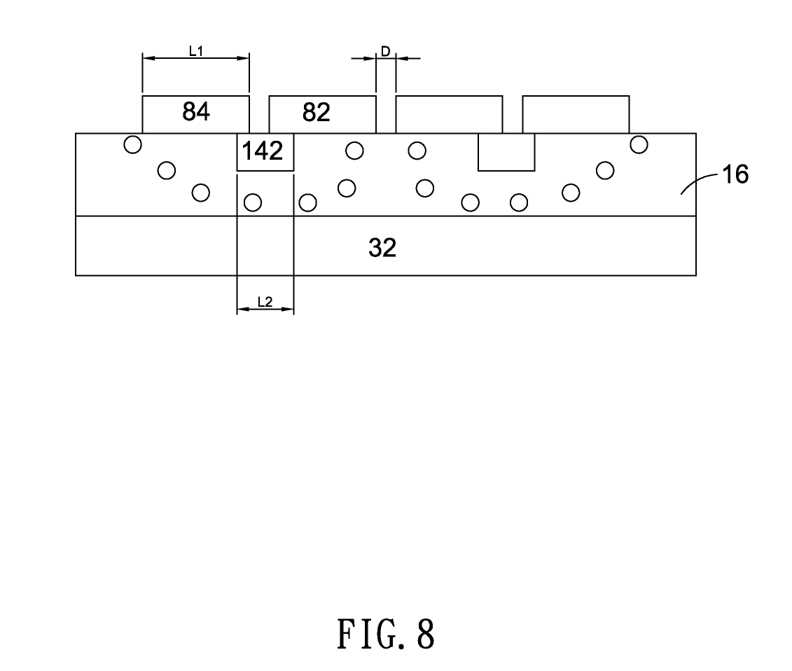

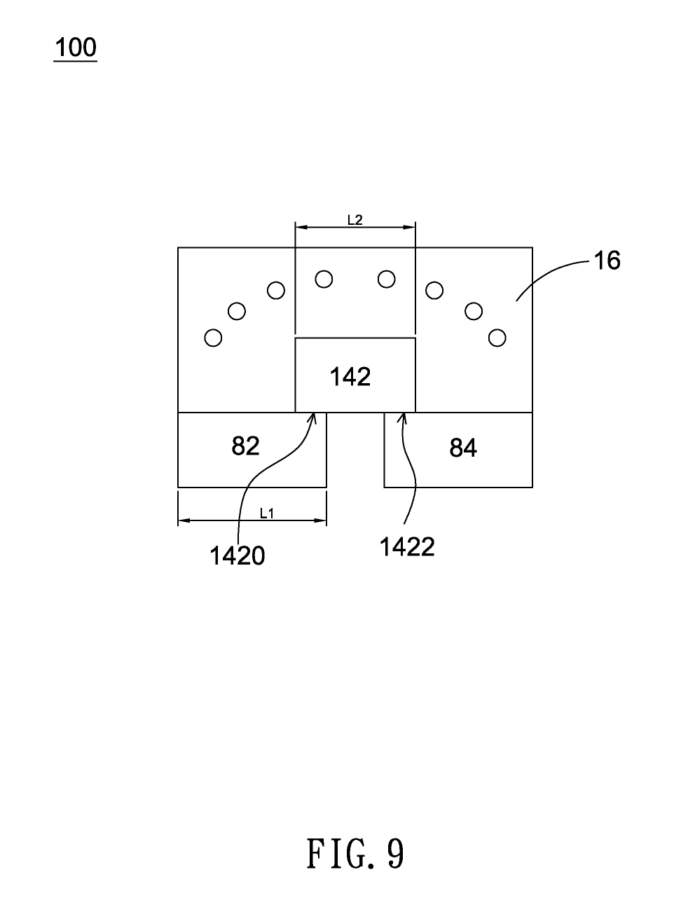

Referring to FIG. 8, a third substrate 32 is attached to the optical layer 16, and the structure is turned over so the third substrate 32 is at the bottom of the structure. Then, the second substrate 22 and the photoresist layer 6 are removed to expose parts of the surface that are not covered by the first pad 82 or the second pad 84. The third substrate 32 can be a carrier supporting the light-emitting chips and the optical layer 16 during the process of removing the photoresist layer 6 and the second substrate 22. A cutting process is performed to singulate the optical layer 16. Then, the third substrate 32 is removed to form a light-emitting device 100 as shown in FIG. 9. In this embodiment, the light-emitting device 100 comprises one light-emitting chip. In another embodiment, the light-emitting device 100 comprises a plurality of light-emitting chips. Moreover, the plurality of light-emitting devices 100, either comprising one chip or multiple chips, can be attached to another substrate. Then the substrate with light-emitting devices 100 can be stretched for different process requirements.

The process to singulate the optical layer 16 and remove the third substrate 32 can be realized in two different methods. The first method is to perform the cutting on the optical layer 16 from the surface having the bonding pads formed thereon in a direction towards the third substrate 32. The optical layer 16 along with the third substrate 32 is then separated by splitting. In another embodiment, the cutting process is performed on both the optical layer 16 and the third substrate 32, so the optical layer 16 and the third substrate 32 can be separated without additional splitting process. After the cutting process, the second chip 142 along with the bonding pads 82, 84 and the optical layer 16 can be picked from the substrate 32 and a light-emitting device 100 as shown in FIG. 9 is formed.

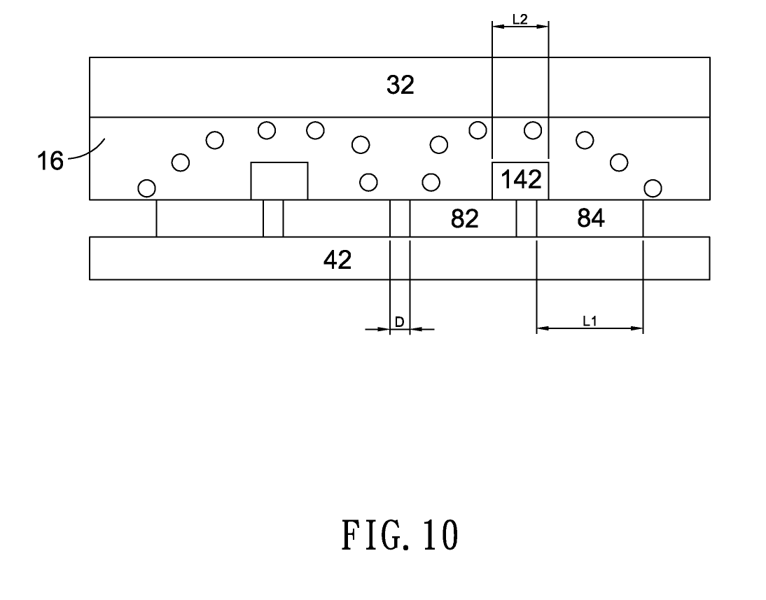

The second method is to perform the cutting processes at least twice. The first cutting process forms multiple trenches on the surface of the optical layer 16 having the bonding pads formed thereon, and the trenches protrude into the optical layer 16 without separating the optical layer 16. Referring to FIG. 10, the fourth substrate 42 is provided to connect with the bonding pads, and the structure is turned over so the fourth substrate 42 is at the bottom side. In one embodiment, the fourth substrate 42 can be a blue tape which can be stretched. A second cutting process is then applied on the surface of the third substrate 32 opposite to the optical layer 16. The second cutting process forms trenches (not shown) extending from the third substrate 32 to the trenches (not shown) in the optical layer 16. So, the optical layer 16 along with the third substrate 32 is separated. The separated third substrate 32 is then removed. Next, the second chip 142 with the bonding pads 82 and 84 and the optical layer 16 can be picked from the fourth substrate 42 to form a light-emitting device 100 as shown in FIG. 9. In another embodiment, the third substrate 32 is removed before the second cutting process and the second cutting process is applied on the surface of the optical layer 16 opposite to the bonding pads.

The first method is more likely to be applied when the “distance” is sufficient to pick the light-emitting device from the third substrate 32, and the second method is more likely to be applied while the “distance” is too small. The “distance” represents the minimum distance between two sidewalls of two bonding pads separately connected to two neighboring chips. For example, the “distance” is the length D in FIG. 8. While the length D is small, the picking process is performed with risk of damaging the light-emitting device. So, the fourth substrate 42 is applied to be stretched to enlarge the length D for picking process as mentioned above. The fourth substrate 42 can also be PVC. The length D is designed to be small for manufacturing as many light-emitting devices as possible on one substrate. The small length D avoids the optical layer 16 from protruding from the part that is not covered by the chip. The small length D also avoids the optical layer protrude from contacting the sidewalls of the bonding pads during the turning process in manufacturing.

Referring to FIG. 9, the light-emitting device 100 comprises an optical layer 16 on the second chip 142 and the first pad 82 and the second pad 84. In other words, both of the first pad 82 and the second pad 84 are under the optical layer 16. The optical layer 16 has a width larger than that of the second chip 142 so the effect of scattering the light emitted from the second chip 142 is improved, and the viewing angle of the light emitted from the second chip 142 is therefore increased. Each of the surfaces of the bonding pads comprises a portion directly contacted with the optical layer 16 and not covered by the second chip 142. The bonding pads can support the optical layer 16 and prevent the optical layer 16 from collapse. The particles of the wavelength conversion material are spread within the optical layer 16 and surround the second chip 142 so the light passing through the sidewall of the second chip 142 can be converted by the wavelength conversion material, and the uniformity of COA (color over angle) of the light-emitting device 100 can be improved. The cross-sectional shape of the optical layer 16 is a rectangular. In another embodiment, the cross-sectional shape of the optical layer 16 can be a quadrangle comprising a trapezoid.

As mentioned above, the second chip 142 further comprises two electrodes (not shown), and the electrodes are respectively connected to the first pad 82 and the second pad 84. In this embodiment, the connection is formed by a bonding process, and the bonding process is performed under a range of temperature between 100˜400° C. and a pressure of about 5800 kgf on a 4″ wafer (the area is about 81 cm²). Under the circumstances, the interfaces between the pads and the electrodes are formed to be eutectic bonding interfaces. To be more specific, the first interface 1420 (between the first pad 82 and one electrode) and the second interface 1422 (between the second pad 84 and the other electrode) are eutectic bonding interfaces, and both comprise eutectic metal alloy. The eutectic metal alloy has a eutectic point lower than 400° C. In another embodiment, the eutectic point is between 100˜400° C.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

1.-10. (canceled)

11. A light-emitting device, comprising:
a light-emitting chip comprising an electrode;
an optical layer surrounding the light-emitting chip and exposing the electrode; and
a bonding pad having a first portion directly connected to the optical layer, and a second portion connected to the electrode with an eutectic bonding interface.

12. The device of claim 11, wherein the optical layer has a width larger than that of the bonding pad.

13. The device of claim 11, wherein the optical layer has an outer surface coplanar with an outer surface of the bonding pad.

14. (canceled)

15. The device of claim 11, wherein the bonding pad is entirely covered by the optical layer.

16. The device of claim 11, wherein the optical layer comprises a wavelength conversion material surrounding the light-emitting chip.

17. The device of claim 11, wherein the optical layer has a cross-section of quadrilateral shape.

18. (canceled)

19. The device of claim 11, wherein the eutectic bonding interface comprises a eutectic alloy having a eutectic point lower than 400° C.

20. (canceled)

21. A light-emitting device, comprising:
a light-emitting chip comprising multiple electrodes;
an optical layer on the light-emitting chip;
a first bonding pad and a second bonding pad connected to the multiple electrodes; and
a wavelength conversion layer covering the light-emitting chip,
wherein the wavelength conversion layer has an asymmetric profile with respect to a vertical center line of the first light-emitting chip.

22. The device of claim 21, wherein the wavelength conversion layer comprises a first tail not exceeding the first bonding pad, and a second tail exceeding the second bonding pad.
